(19) United States
(12) Patent Application Publication
(10) Pub. No.: US 2024/0405244 A1
(43) Pub. Date: Dec. 5, 2024

(54) H+ Conductivity for Fuel Cell Electrolyzers

(71) Applicant: Forge Nano Inc., Thornton, CO (US)

(72) Inventors: Matthew WEIMER, Thornton, CO (US); Sara HARRIS, Thornton, CO (US); Arrelaine DAMERON, Boulder, CO (US)

(21) Appl. No.: 18/803,698

(22) Filed: Aug. 13, 2024

Related U.S. Application Data
(63) Continuation-in-part of application No. PCT/US24/15884, filed on Feb. 14, 2024.
(60) Provisional application No. 63/445,710, filed on Feb. 14, 2023.

(51) Int. Cl. H01M 8/18; H01M 4/86; H01M 4/96; H01M 8/1016

(52) U.S. Cl. CPC H01M 8/188; H01M 4/96; H01M 8/1016; H01M 2004/8684

(57) ABSTRACT

A doped silica layer on a substrate comprises a substrate and a doped silica layer that has a thickness of 5 to 1000 nm, and a dopant:silicon atomic ratio of 0.5:99.5 to 15:85. The dopant is preferably P⁺⁵. The invention includes an electrolyzer comprising the doped silica layer and a method of electrolyzing water to produce hydrogen using the electrolyzer. The doped silica can be made by applying a silica layer by atomic layer deposition (ALD) and treating the silica layer with a phosphorus gas in which phosphorus is in the +3 valence state.

### RELATED APPLICATIONS

This application is a Continuation-In-Part of PCT/US24/15884 filed 14 Feb. 2024 and U.S. Provisional Patent Application Ser. No. 63/445,710, filed 14 Feb. 2023.

### INTRODUCTION

H₂ is a carbon-free and versatile energy carrier, anticipated to be an integral part of the clean energy future. Hydrogen fuel has significant relevance today; currently comprising roughly 1.5% of global energy use. Unfortunately, over 95% of H₂ production comes from highly polluting, oil and coal, or grey (methane) sources. Currently, the cost of green H₂ from electrolysis is not competitive with fossil fuel sources. One pathway to drive down cost is by increasing the efficiency of polymer electrolyte membrane (PEM) electrolyzes by reducing the ohmic overpotential required by the cell. In this work, the path to ohmic overpotential reduction, which is partially dictated by the membrane thickness (see Han, et al., Int. J. Hydrogen Energy, 40, 2015) and the H⁺ conductivity, is achieved by replacing Nafion with an ultra-thin proton-conducting oxide membrane (POM) deposited by ALD (Atomic Layer Deposition). An SiO₂ ALD film deposited with a unique catalytic process has been synthesized and tested over a range of temperatures and thickness to measure the H⁺ conductivity and gas permeation (H₂). H⁺ permeability of these SiO₂ films were prohibitively low, so dopants were explored to increase H⁺ permeability without sacrificing other requirements. Phosphate, PO₄⁻³ species were doped into an SiO₂ ALD film using two novel ALD precursors for PO₄⁻³ doping. As background, see Henderick, L., et al., Appl. Phys. Rev. 9, 011310, 2022 and Prakash, et al., J. Pow. Sources, 175, 2008. Both precursors were found to incorporate into the growing SiO₂ film, as measured by X-ray photoemission spectroscopy (XPS), but not grow a P₂O₃ or P₂O₅ monolith with H₂O, O₂ or O₃. The largest PO₄⁻³ percent incorporation was observed in an ABC-type ALD sequence, where the PO₄⁻³ precursor did not see a separate oxidant. All POₓ:SiO₂ films also showed a decrease in RI. H⁺ permeability improved with PO₄₋₃ addition. An ABC-type ALD processes showed the largest improvement, almost an order of magnitude from 8.4×10⁻⁵ to 2.2×10⁻³ S/cm in acidic solution with a rotating disk electrode at room temperature. Unexpectedly, the addition of PO₄⁻³ also improved H₂ permeability by almost 5×, from 3.8×10⁻¹⁰ to 1.3×10⁻¹⁰ S/cm. Importantly, ALD POM films have the potential to directly coat high surface area porous transport or gas diffusion layers for integration into current PEM electrolyzer cells, further improving efficiency. This work enables building full electrolyzers that employ a novel ultra-thin ceramic membrane suitable for making green H₂.

Water electrolysis powered by renewable energy is an attractive approach to generating carbon-free, energy-dense hydrogen (H₂) fuel that is expected to be a key enabler of industrial decarbonization. Globally, H₂ usage is currently below 1 million metric tons/year but projected to grow to 7 million tons/year by the year 2030. In the U.S., Mckinsey & Co. projects revenue from H₂ to be $140 billion/year by 2030 and to support ≈700,000 jobs. However, large-scale deployment of so-called green hydrogen produced by electrolysis is hindered by its relatively high levelized cost of hydrogen (LCOH, $3-$8/kg H₂) compared to “blue H₂” produced from CO2-emitting steam methane reforming (SMR) ($0.70-2.10/kg H₂). Presently, the price of electricity remains the single largest cost contributor to LCOH from water electrolysis, creating a need to increase the energy efficiencies of electrolyzers. Fortunately, reductions in electricity prices from solar and wind are helping to reduce the electricity cost contribution to LCOH, although the availability of low cost electricity (<2¢/kWh) from these variable renewable energy (VRE) generators is generally less than 45%. 3 As a result, electrolyzers operated in areas of high VRE deployment can be expected to be hamstrung by lower capacity factors, creating a second urgent need: decreasing the capital costs (Capex) of electrolyzers. Electrolyzer capex is already decreasing thanks to economies of scale as the industry grows, but more rapid decreases in Capex through advances in manufacturing and improved electrolyzer performance (i.e., higher current density and/or efficiency) are needed. The exact performance and Capex targets for electrolyzers to compete with SMR are highly dependent on the price and availability of electricity, but it is generally understood that next generation water electrolyzers capable of operating at significantly higher current densities and energy efficiencies are needed for green hydrogen to reach parity with blue H₂ in the next 5-10 years.

Today's electrolyzer industry is dominated by two technologies: alkaline and polymer electrolyte membrane (PEM) electrolyzers. Alkaline electrolyzers typically use ˜30 wt % KOH (aq) as the electrolyte and operate with current densities between 0.1-0.4 A/cm2 with HHV stack efficiencies of 75-80%. PEM electrolyzers utilize thin Nafion solid electrolyte membranes that are sandwiched between porous anode and cathode layers. The so-called “zero-gap” geometry and active water management of PEM electrolyzers enables significantly lower ionic resistances, allowing them to operate at 1-2 A/cm2 current densities with comparable efficiencies to alkaline electrolyzers. While the more mature alkaline technology is still expected to be important in the near term, the majority of R&D efforts have shifted towards advancing PEM electrolyzer concepts as the technology of the future, thanks to their ability to operate at 2 A/cm2, and their potential to operate at even higher current densities. However, the gap between electrodes in these “zero-gap” PEM electrolyzers is not actually zero; rather, the Nafion membranes typically have a thickness of 125-250 um. While this may seem thin, ohmic resistance associated with ion transport across the membrane becomes the dominant loss mechanism at high current densities (>2 A/cm2). Researchers have attempted to reduce these losses by using thinner Nafion membranes, but limited gains have been observed due to decreased manufacturing yields and mechanical failure associated with swelling and creeping phenomena that is inherent to many polymeric membranes like Nafion when they are in contact with water. Furthermore, it is well known that the proton conductivity of Nafion decreases for thinner membranes while gas permeability (H₂/O₂) tend to increase. It is likely that, even with development, it will be difficult to achieve membrane thicknesses much below 50 microns. While still worthy of pursuit, such efforts are not likely to lead to step changes in electrolyzer performance. Herein, we describe a class of membrane materials and approach to manufacturing PEM electrolyzers with membranes that are 2-4 orders of magnitudes thinner than Nafion membranes and the ability to reduce ionic resistances below 0.2 V at current densities of 5 A/cm2 or higher.

To overcome the limitations of conventional polymeric membranes like Nafion, we use proton-conducting (SiOx) membranes that are substantially silicon dioxide, but dopants may slightly change the stoichiometry. SiOx materials have long been known for their ability to conduct protons (H+), but their lower conductivities than Nafion at low temperatures have precluded their consideration as membrane materials in conventional catalyst-coated membranes (CCMs). Fortunately, the lower H+ conductivity is not problematic if the membrane can be made very thin, while providing a sufficient barrier to gas permeation. We demonstrate that ultrathin, continuous oxide membranes having thicknesses that are 2-4 orders of magnitude lower than those used for Nafion in PEM electrolyzers can decrease membrane resistance by >80%. Lower thicknesses are possible with thin oxide membranes thanks to: (i) their higher densities that can suppress gas crossover (which occurs through pores); (ii) their high mechanical strength and resistance to deformation compared to polymers; and (iii) recent advances in fast atomic layer deposition (ALD) fabrication approaches that can deposit conformal nano-to-micron scale oxide coatings on rough surfaces in a high-throughput manner. While oxide-based membranes are ubiquitous for high-temperature solid-oxide fuel cells and electrolyzers, there are no reports of oxide-based membranes for low-temperature (<0.2 V at current densities up to 5 A/cm²) electrolyzers. In Table 1, PEM and POM electrolyzer operation is considered for two operating modes: a “standard” current density (i) of 1.7 A/cm² and a high current density of i=4.25 A/cm². Using a 1-dimensional (1D) electrolyzer model that assumes constant temperature and kinetic overpotential losses between the two types of electrolyzers, the gain in electrolyzer efficiency (ηE) was then computed, with the results shown in the last column of Table 1. As expected, the reduction in membrane resistance leads to efficiency gains in both cases, but gives the largest advantage for high current density operation for which the membrane ohmic losses normally dominate polarization behavior. The high current density (i.e., high capacity) operating mode is most attractive for a renewable energy future where low-cost electricity can be sourced from wind and/or solar (e.g. 2¢/kWh based on the DOE Sunshot target for 2030), but might only be available 30-40% of the time. These efficiency gains at high current density translate to reductions in electrolyzer stack costs from current values of ≈$400/KW to ≈$70/KW. This reduction in stack costs is consistent with the DOE's Energy Earthshot Initiative targeting a LCOH of $1/kg H₂ by 2031. Achieving $1/kg H₂ would be transformative in that it would allow H₂ from water electrolysis to undercut H₂ from SMR, and directly compete with the price of gasoline at the pump.

TABLE 1
Target technical metrics of the proposed ultrathin oxide membranes and associated
POM electrolyzer compared to metrics for a conventional PEM electrolyzer based on
standard Nafion-117 membrane. Analysis is based on a ID electrolyzer model that assumes
constant temperature and catalyst loadings for both types of electrolyzers.

| | Membrane characteristics | | Electrolyzer performance metrics | |
|---|---|---|---|---|
| Electrolyzer | Membrane | Membrane | Current | Efficiency gain |
| Technology | thickness (μm) | resistance (mΩ · cm²) | density (i) | (absolute, wrt PEM) |
| Baseline PEM using | 178 | 180 | 1.70 A cm⁻² | 0% |
| Nafion-117 | | | | |
| POM (standard i) | <1 | 30 | 1.70 A cm⁻² | 10% |
| POM (high i) | <1 | 30 | 4.25 A cm⁻² | 20% |

### SUMMARY OF THE INVENTION

In one aspect, the invention provides an electrolyzer, comprising: an anode, a cathode, and a doped silica electrolyte layer; wherein the anode and the cathode separated by one μm or less; wherein the anode and the cathode are separated by the doped silica electrolyte layer; wherein the doped silica electrolyte layer has: a thickness of 5 to 1000 nm; a dopant:silicon atomic ratio of 0.1:99.5 to 15:85; and one or any combination of the following room temperature properties: a H+ permeability (cm²/s)≥5×10⁻¹¹; a H+ conductivity of at least 0.5 mS/cm, or at least 1.0 mS/cm, or in the range of 0.5 to 5 mS/cm, or in the range of 1.0 to 4 mS/cm; an H₂ permeability of 8×10⁻¹¹ cm²/s or less; or a vanadium ion permeability of 1×10⁻⁸ cm²/min or less. The anode and cathode can be any anode or cathode known in the prior art; anode and cathode are typically plate-shaped; the anode typically has a catalyst such as Pt; a common material comprises carbon paper.

The electrolyzer can be further characterized by one or any combination of the following: wherein the doped silica electrolyte layer has a thickness in the range of 5-500, 5-200, 5-100, 10-1000, 10-500, 10-200, 10-100 nm; wherein the doped silica electrolyte layer has a dopant:silicon atomic ratio of 0.2:99 to 15:85; 0.5:99 to 15:85; or 1:99 to 10:90; or 1:99 to 5:95; wherein the doped silica electrolyte layer has a H+ conductivity ≥1×10⁻³; or in the range of 5×10⁻⁵ to 1×10⁻³; or in the range of 8×10⁻⁵ to 2×10⁻³ cm²/s; wherein the dopant is P⁺⁵; wherein the electrolyzer is a redox flow battery; wherein the doped silica electrolyte layer is deposited on the anode by atomic layer deposition; wherein the anode comprises carbon paper; wherein no fluoropolymer is present in the electrolyzer; wherein the dopant is P⁺⁵; and/or wherein the doped silica electrolyte layer has a H+ permeability ≥1×10⁻¹⁰; or in the range of 5×10⁻¹¹ to 5×10⁻¹⁰; or in the range of 5×10⁻¹¹ to 2×10⁻¹⁰ cm²/s and a H+ conductivity of ≥1×10⁻³; or in the range of 5×10⁻⁵ to 2×10⁻³; or in the range of 5×10⁻⁵ to 2×10⁻³ S/cm.

In another aspect, the invention provides a doped silica layer on a substrate, comprising: the substrate; and a doped silica layer that has: a thickness of 5 to 1000 nm; a dopant:silicon atomic ratio of 0.1:99.5 to 15:85; and wherein the dopant is P⁺⁵.

The doped silica layer on a substrate can be further characterized by one or any combination of the following: the layer having a thickness in the range of 5-500, 5-200, 5-100, 10-1000, 10-500, 10-200, or 10-100 nm; the layer having a dopant:silicon atomic ratio of 0.2:99 to 15:85; 0.5:99 to 15:85 or 1:99 to 10:90; or 1:99 to 5:95; the layer having a H+ conductivity ≥1×10⁻³; or in the range of 5×10⁻⁵ to 1×10⁻³; or in the range of 8×10⁵ to 2×10⁻³ S/cm; the layer having a H+ permeability >1×10⁻¹⁰; or in the range of 5×10⁻¹¹ to 5×10⁻¹⁰; or in the range of 5 ×10⁻¹¹ to 2×10⁻¹⁰ cm²/s; and/or wherein the substrate comprises a cathode, an anode, or glass.

In a further aspect, the invention provides a method of making a doped silica layer on a substrate, comprising: providing a substrate; applying a silica layer by CRISP ALD onto the substrate; and treating the silica layer with a phosphorus-gas in which phosphorus is in the +3 oxidation state. In some embodiments, phosphorus-gas comprises trialkoxyphosphite or trimethoxyphosphite. The method may, for example, comprise from 5 to 30 cycles CRISP ALD followed by one to five cycles of treatment with the phosphorus-gas. To form a thicker layer, a cycle comprises from 5 to 30 cycles of CRISP ALD followed by one to five cycles of treatment with the phosphorus-gas; and comprising a plurality of cycles to form the thicker layer. Preferably, the applying step is conducted at a temperature of 200° C. or less, or 175° C. or less, or 150° C. or less.

The invention includes methods of electrolyzing water in which protons pass through the membrane where they form dihydrogen. In other aspects, the invention includes optical devices that utilize the inventive coating. RI (refractive index) can be varied according to the invention.

The invention is further illustrated in the examples below. In some preferred embodiments, the invention may be further characterized by any selected descriptions from the examples, for example, within ±20% (or within ±10%) of any of the values in any of the examples, tables or figures; however, the scope of the present invention, in its broader aspects, is not intended to be limited by these examples.

As is standard patent terminology, the term “comprising” means “including” and does not exclude additional components. Any of the inventive aspects described in conjunction with the term “comprising” also include narrower embodiments in which the term “comprising” is replaced by the narrower terms “consisting essentially of” or “consisting of.” As used in this specification, the terms “includes” or “including” should not be read as limiting the invention but, rather, listing exemplary components. As is standard terminology, “systems” include to apparatus and materials (such as reactants and products) and conditions within the apparatus. All ranges are inclusive and combinable. For example, when a range of “1 to 5′ is recited, the recited range should be construed as including ranges “1 to 4”, “1 to 3”, “1-2”, “1-2 & 4-5”, “1-3 & 5”, “2-5”, any of 1, 2, 3, 4, or 5 individually, and the like.

### BRIEF DESCRIPTION OF THE DRAWINGS

FIG. 1 shows a plot of ohmic drop versus membrane thickness.

FIG. 2 shows a polarization curve for a typical PEM electrolyzer.

FIG. 3: Percent difference in thickness of an ALD POx doped SiO₂ thin film from the thickness of a “standard” undoped SiO₂ ALD film as a function of the percent of POx cycles in total cycles (#POx cycles/(#POx cycles+#SiOx cycles)) for films made using the super-cycle ALD scheme. Data points are shown for films made using H₂O (dark blue circles) and O₃ (orange circles) as the complementary precursor used with the dopant, phosphite, precursor.

FIG. 4: Bar chart of the Percent difference in thickness of an ALD POx doped SiO₂ thin film from the thickness of a “standard” undoped SiO₂ ALD film as a function of the percent of POx cycles in total cycles (#POx cycles/(#POx cycles+#SiOx cycles)) for films made using the super-cycle ALD scheme. A positive number indicates an increase in thickness over the standard, while a negative number indicates a thinner film. This chart only shows the 20:2 ratio to highlight the difference between the four processes.

FIG. 5: Bar chart comparing GPC at 80 nm on Si for the four POx doped SiOx processes.

FIG. 6: XPS P content and H⁺ permeability of the four POx doped SiOx processes.

FIG. 7 shows various data for P-doped silica films. Samples that had at least 0.5 atom % P showed a ten times improvement in P_{H+} compared to undoped silica. Pox, atom % from XPS was 0.92, 0, 0.63, 0.02, and 0 from Samples 1-5, respectively.

FIG. 8 shows plateaus from rotating disk electrode measurements and calculated H+ permeabilities.

FIG. 9 shows a plot of permeability of various doped samples.

FIG. 10 shows H⁺ Conductivity on a log scale with respect to deposition temperature for POx doped and undoped ALD SiOx. Nafion baseline is shown as the dashed line.

FIG. 11 shows a membrane-coated scaffold concept based on an ultrathin proton-conducting oxide membrane (not to scale), shown in discharge.

### DETAILED DESCRIPTION OF THE INVENTION

An objective of this invention is to controllably incorporate POₓ ALD chemistry to increase the H+ conductivity of ultra-thin electrolyzer membranes. The catalyzing Reactions for Induced Surface Process Atomic Layer Deposition (CRISP ALD) process is a known process described in patents such as U.S. Pat. No. 7,250,083 which is incorporated herein as if reproduced in full below. A generalized CRISP method of treating a solid film on a substrate may include introducing a plurality of catalyzing reactants into a reaction chamber containing the solid film, so that the catalyzing reactants react in a continuous and non-saturating catalyzing reaction that generates a volatile by-product and an intermediate reactive molecular fragment, whereby the intermediate reactive molecular fragment reacts with the solid film in a fragment-film reaction, and further includes controlling a temperature of the chemical film to control the treating. In certain embodiments, the intermediate reactive molecular fragment comprises hydrogen, and the hydrogen is incorporated into the chemical film during the fragment-film reaction. In other embodiments, the intermediate reactive molecular fragment comprises a hydrogen atom, and the hydrogen improves the interface between the solid film and the substrate. In an example of a film treatment utilizing a CRISP method, the intermediate reactive molecular fragment comprises a P dopant atom, and the P dopant atom is incorporated into the chemical film during the fragment-film reaction.

The method utilized was the BEMAS/CRISP SiO₂ ALD process modified by doping. Initial tests explored the ability of different chemistries to incorporate into the growing SiO2 film, then the impacts of the POₓ doping on H+ conductivity and H₂/O₂ permeation were characterized. Reactive precursors include: bis(ethylmethylamino) silane (BEMAS), (H₃Si) 2NSiH₂NEt₂ (Orthrus), and bis(diisopropylamino)disilane (BDIPADS). Samples were sent for x-ray reflectivity (XRR) and x-ray photoemission spectroscopy (XPS) metrologies, and for further characterization (H+ conductivity, O₂/H₂ gas permeation, SEM). Initial chemistries explored were trimethyl phosphite (P(OMe)₃) and triethyl phosphite (P(OEt)₃). H₂O, O₃, and no conversion step were explored during development. For example, 20 cycles of the BEMAS/CRISP SiO₂ process were run, then two (2) cycles of the P(OMe)₃/H₂O process were run. A 22 super cycle system was run for 5 iterations and the thickness was checked against a separate wafer with the same total cycles of SiO₂ (100 cycles). If the thickness was more or less than expected, it was preliminarily assumed that some POₓ was incorporated or there was some impact from the ligands. The objective is to be able to controllably integrate P from 1-15% (atomic %). Additionally, more traditional P-doping ALD precursors such as diethyl phosphoramidate (DEPA) and trimethylphosphate (TMPO) were also tested. All tests in this project were performed at 250° C. wafer temperature.

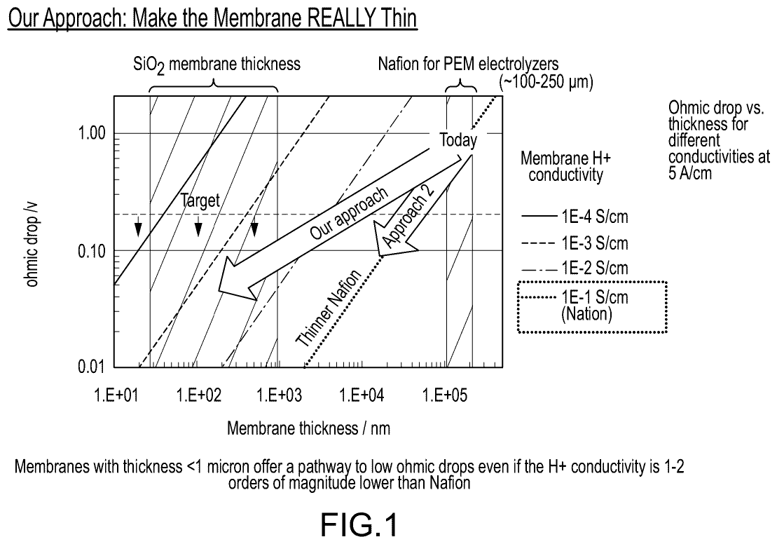

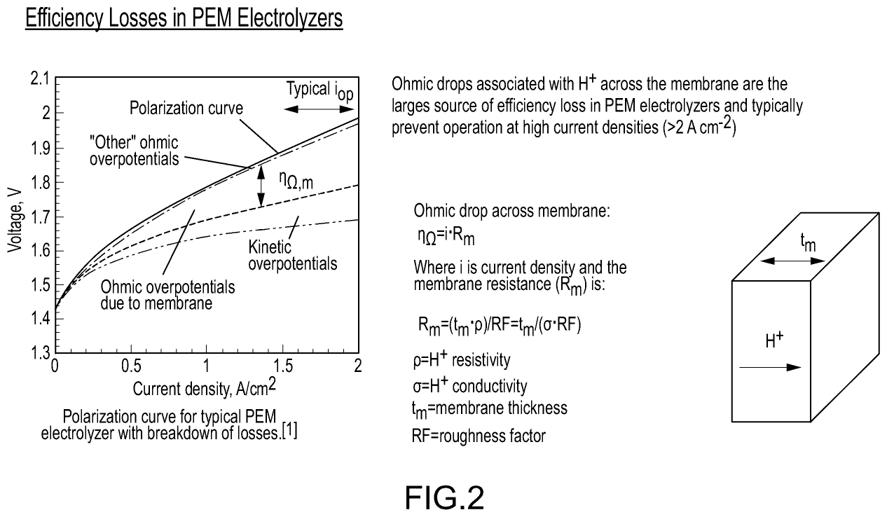

A thinner film would have lower H+ permeability than Nafion. The thinner total thickness will allow for lower H+ permeability, but still have higher efficiency. FIG. 1 shows Ohmic drop vs membrane thickness at different H+ permeability/conductivities. Note here that ohmic drop is the largest source of efficiency loss in electrolyzers and prevents going to higher current densities (higher current densities can also increase efficiencies). POx doping increases the H+ conductivity of our undoped ALD film by at least 5×, with a membrane thickness between 10-100 nm, without sacrificing the gas permeability of the films.

Prior to deposition on Pt samples, POₓ precursors were screened in two ways. First, a traditional ALD cycle, consisting of a P precursor and oxygen source, were added into a super cycle periodically, to see how the GPC was impacted when compared to an undoped SiO₂ (BEMAS/CRISP) film deposited on a different wafer. In addition, the P precursor was added into the BEMAS/CRISP process without a conversion step before and after the CRISP step and the thickness was compared to the undoped SiO₂ monolith. The reaction of BEMAS with both phosphite precursor was tested and found to yield no reaction. Deposition temperature was held at 250° C. for all films. Thickness during development was investigated with the single wavelength (633 nm) Stokesmeter ellipsometer with a fixed refractive index (RI) of 1.44. For thick films, >80 nm, the thickness, RI, and extinction coefficient (k) were determined using spectroscopic ellipsometry (SE) at a fixed angle (75°). By modeling cos (24′) and sin (24′) cos (4), measured from data generated using a dual light source over the range of 225-1000 nm (combined deuterium and halogen sources) and a Si based array detector. A regression analysis was explored via the Levenberg-Marquardt fitting algorithm employing a dispersion method (Cauchy, Exponential, Sellmeier, and Tauc-Lorentz) and the model was fit over the wavelength range of 250 to 1000 nm. Growth per cycle (GPC), RI, k are listed in Table 2 below for the two ALD processes deposited on all samples. Note that the goodness of fit (GOF) is a term that measures the accuracy of the model to the raw data. A number greater than 0.96 is considered an accurate fit.

TABLE 2
Film properties of POₓ:SiO₂ on Si wafers as
modeled from Spectroscopic Ellipsometry

| | | GPC | | | |
|---|---|---|---|---|---|
| | GPC | (Å/cy) | | | |
| | (Å/cy) | (SiO₂ | Refractive | Extinction | |
| Process | (all cycles) | only) | Index | coefficient | GOF |
| BEMAS/CRISP/ | 0.945 | 0.945 | 1.439 | 0.0 | 0.96 |
| P(OEt)₃ | | | | | |
| P(OEt)₃/H₂O | 1.121 | 1.231 | 1.439 | 0.0 | 0.96 |
| BEMAS/CRISP/ | 1.056 | 1.056 | 1.436 | 0.0 | 0.96 |
| P(OMe)₃ | | | | | |
| P(OMe)₃/H₂O | 1.124 | 1.235 | 1.430 | 0.0 | 0.96 |
| BEMAS/CRISP | 1.21 | 1.21 | 1.445 | 0.0 | 0.99 |

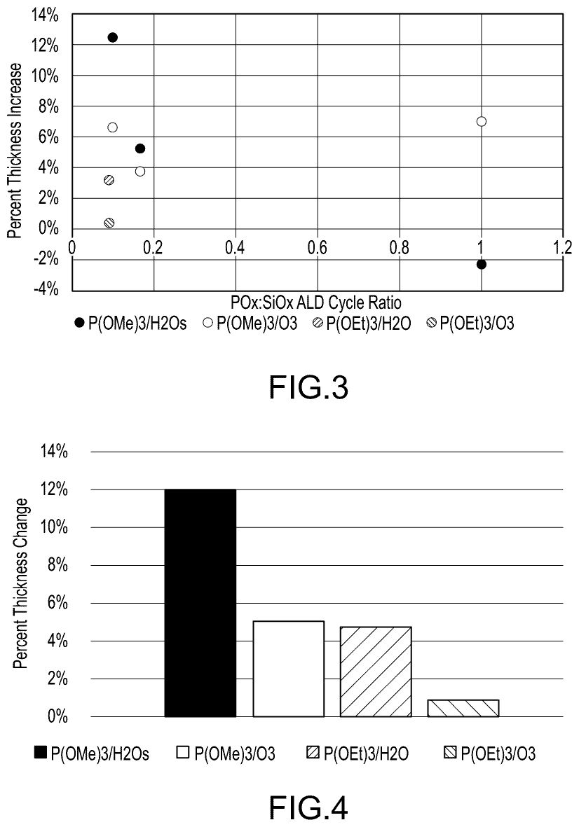

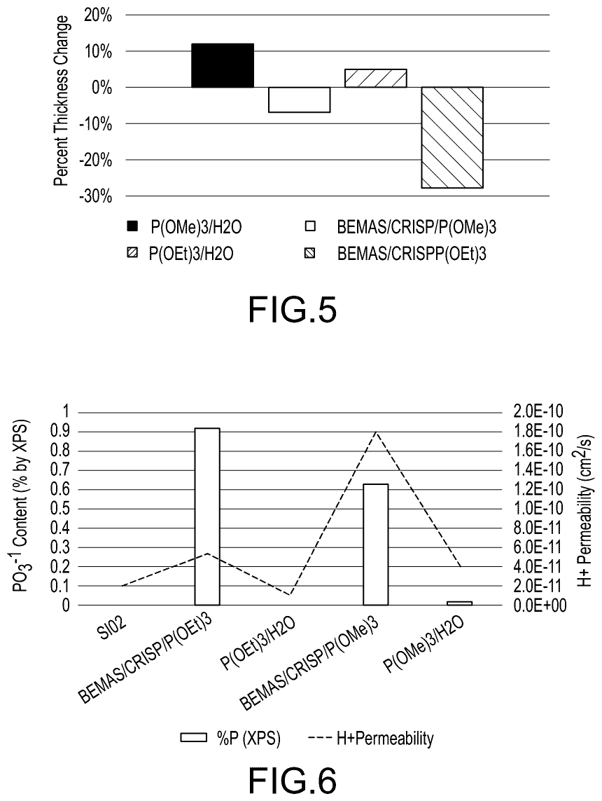

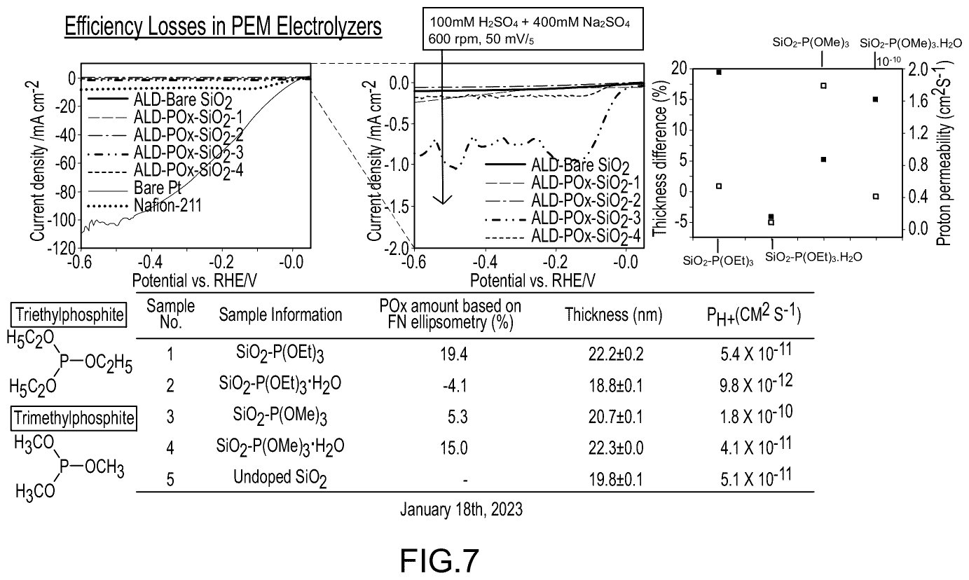

Thickness difference was observed for both the P(OEt)₃ and P(OMe)₃ systems with H₂O and O₃. At thin thickness, it was observed that the thickness increase with respect to SiO₂ to POₓ ratio decreased with more POₓ cycles for the P(OMe)₃/H₂O process and was relatively flat for the P(OEt)₃/O₃ process, as shown in FIG. 3. In addition at the 10:1 (SiO₂:POₓ) cycle ratio (deposited as 20:2 and shown as the 9% point in FIG. 3, the P(OEt)₃/H₂O process had a smaller change than the P(OMe)₃/H₂O process and the P(OEt)₃/O₃ process did not have a statistically significant thickness change, as observed in FIG. 3. The same data for the 10:1 ratio is shown in FIG. 4 as a bar chart. When comparing all four processes, the P(OMe)₃/H₂O process showed the largest increase in thickness and the P(OEt)₃/O₃ process was essentially the same thickness of film. The P(OMe)₃/O₃ and P(OEt)₃/H₂O processes showed essentially the same thickness increase. Interestingly, once a thicker monolith sample was deposited, the GPC of the total stack was less than a SiO₂ monolith. This could be due to an improper model for fitting the thinner films, or a dynamic behavior of the POₓ incorporation (for examples the H-OEt or H-OMe by-products could be causing inhibition as observed by Elam and co-workers¹). However, if one compares the GPC of just the SiO₂ cycles versus the baseline, both processes with H₂O as a co-reactant have a higher GPC than baseline and both ABC-type ALD (BEMAS/CRISP/P(OR)₃) have a lower GPC, as seen in FIG. 5. These data strongly suggests that the GPC for POₓ is less than SiO₂, but we have not been able to eliminate the other hypothesis above. Across all tests, the RI of the films with POₓ doping came in lower than the monolith. Again, the P(OMe)₃/H₂O process showed the largest decrease in RI, while the two P(OEt)₃ processes showed the least change. The ability to decrease the RI of SiO₂ can have implications for the optics world and SiO₂ based lasers. From these data, it was determined to further investigate the 10:1 cycle ratio of each phosphite with H₂O. Thick films, ˜80 nm, were deposited on Si and sent for further analysis (XPS, Raman, XRR, and XRD). ¹ Yanguas-Gil, A., Peterson, K. E., Elam, J. W., Chem. Mater. 2011, 23, 4295-4297 and Yanguas-Gil, A., Libera, J. A., Elam, J. W., Chem. Mater. 2013, 25, 4849-4860.

Both phosphites were introduced with a conversion half-cycle (H₂O or O₃) into the BEMAS/CRISP process both before and after the CRISP conversion step. See Table 3. From the data, it can be seen that the addition of either phosphite precursor after BEMAS (before the CRISP conversion step), results in no distinct change from the baseline BEMAS/CRISP process. Neither the GPC nor the RI are significantly different than bulk ALD SiO₂ deposited with BEMAS/CRISP. This result is somewhat expected given that the two precursors (BEMAS/phosphite) are not reactive with each other and that the BEMAS/CRISP process has such a high GPC. Conversely, when either precursor was dosed after the CRISP step (before BEMAS), there was a distinct reduction in GPC and RI. Here, the GPC decreased slightly more for the P(OEt)₃ process, but the RI reduced more for the P(OMe)₃ process. To further test the BEMAS/CRISP/phosphite processes, thick (˜80 nm) films were deposited on Si and sent out for further analysis (XPS, Raman, XRR, and XRD).

TABLE 3
Film properties of POₓ:SiO₂ on Si wafers for
the process with no POₓ conversion step.

| | GPC | Refractive | Extinction | |
|---|---|---|---|---|
| Process | (Å/cy) | Index | coefficient | GOF |
| BEMAS/CRISP/ | 0.945 | 1.439 | 0.0 | 0.96 |
| P(OEt)₃ | | | | |
| BEMAS/P(OEt)₃/ | 1.171 | 1.447 | 0.0 | 0.96 |
| CRISP | | | | |
| BEMAS/CRISP/ | 1.056 | 1.436 | 0.0 | 0.96 |
| P(OMe)₃ | | | | |
| BEMAS/P(OMe)₃/ | 1.171 | 1.440 | 0.0 | 0.96 |
| CRISP | | | | |
| BEMAS/CRISP | 1.21 | 1.445 | 0.0 | 0.99 |

As noted above, all of processes that were identified, were also deposited on Pt on Si wafers to perform extra analytical measurements, including H+ and H₂/O₂ conductivities. Prior to introduction into the chamber, the Pt on Si samples on 4″ wafers were cleaved in half, then sonicated in IPA for 5-10 minutes, then transferred to DI water, and dried with compressed N₂ air in the clean room. All Pt on Si half 4″ wafers were run on 8″ carrier wafers. Prior to ALD, all samples had 30 s O₃ exposure and 5-minute outgas at the deposition temperature. To assist in nucleation, all Pt on Si samples had 10 cycles of double dose of BEMAS/CRISP, with 2× the purge time for each half-cycle. It was observed that this was not necessary and did not have a drastic impact on nucleation behavior, but all previous tests on Si wafers were run with a nucleation layer of 10 BEMAS/CRISP layers as convention. Most sample runs proceeded without incident. No obvious color change was noted on sample on Pt that were 12-15 nm. Thicker samples on Si had a distinct color difference than uncoated Si. After deposition, all thin Pt on Si (5 total) and thick samples on Si wafers (4 total) were packaged in separate 4″ wafer carriers for Pt and 2″ wafer carriers for Si wafers for further testing.

H+ permeability testing found that the ABC type ALD films with both precursors showed an increase in permeability, as shown in FIG. 6.

Interestingly, only the P(OMe)₃/H₂O sample showed a slight increase in permeability, while the P(OEt)₃/H₂O sample did not show a significant difference from baseline. The best performing film was the BEMAS/CRISP/P(OMe)₃ film, which showed almost an order of magnitude increase in H+ permeability over the baseline SiO₂ film. The BEMAS/CRISP/P(OEt)₃ film showed a 2.5× increase and the P(OMe)₃/H₂O film showed a 2× increase in H+ permeability. These data are supported by XPS measurements that show P (5+) (PO₃⁻¹) content (no other P species were observed) for both ABC-type ALD processes and the P(OMe)₃/H₂O, but not the P(OEt)₃/H₂O process. There is a correlation between the P % and the H+ permeability, at least between each precursor. For example, the two P(OMe)₃ sample H+ permeabilities are directly related to the P content, but the P(OEt)₃ sample showed the highest P %, but intermediate H+ permeability.

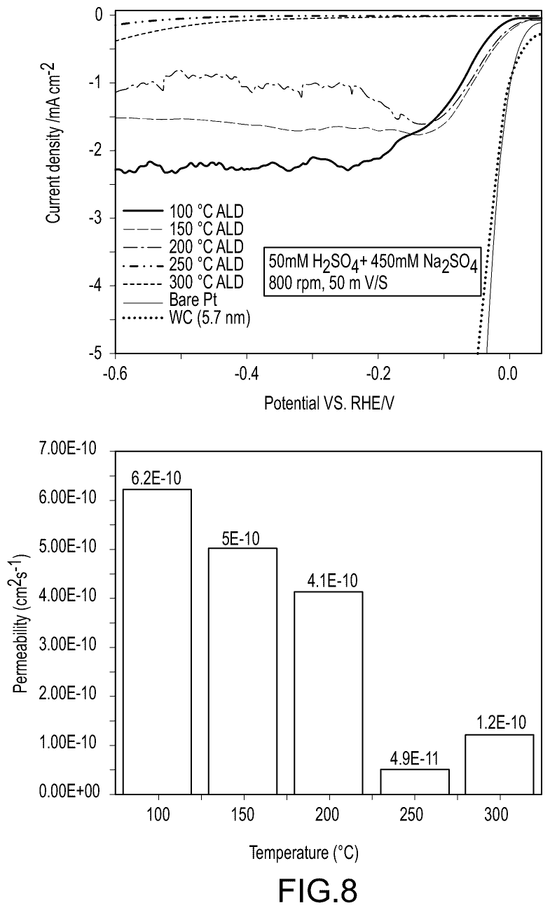

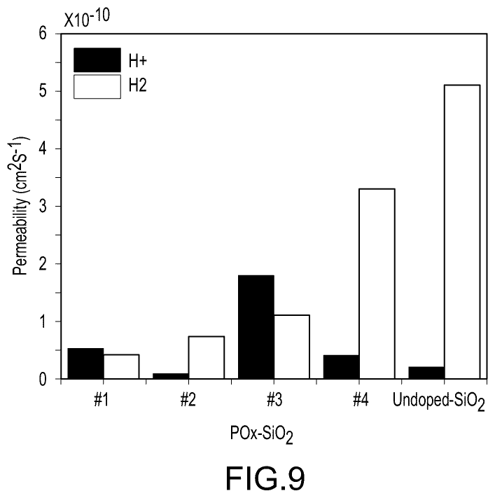

H⁺ permeabilities are measured with a 3 electrode setup utilizing a rotating disk electrode (which helps to minimize bubble formation on the electrode giving more reliable results) for the sample, a carbon rod for the counter electrode and Ag/AgCl for the reference electrode, at room temperature in an acid solution of H₂SO₄/Na₂SO₄ (the concentrations depend on the type of measurement but values may range from 5 to 500 mM). The disk can rotate from 5 to 1000 rpm (rotations per minute) while the potential is swept from negative to positive potential (with respect to RHE, reversible hydrogen electrode) preferably at a rate of 50 mV/s (but vary over a range of 1 to 500). The current density is measured, which relates to the amount of H⁺ moving across the membrane, and a plateau can be found. The more negative the plateau current density, the more H⁺ moves across the membrane. FIG. 8 shows the plateau and the calculated H⁺ permeabilities to illustrate this last point.

### General Description of Atomic or Molecular Layer Deposition

Atomic layer-controlled growth techniques permit the deposition of coatings of about 0.1 to about 5 angstroms in thickness per reaction cycle, and thus provide a means of extremely fine control over surface coverage or coating thickness. Thicker coatings can be prepared by repeating the reaction sequence to sequentially deposit additional layers of the coating material until the desired coating thickness is achieved.

The coating is deposited in an Atomic Layer Deposition (ALD) or Molecular Layer Deposition (MLD) process. In the ALD/MLD process, the coating-forming reaction is conducted as a series of (typically) two half-reactions. In each of these half-reactions, a single reagent (precursor) is introduced into contact with the substrate surface. Conditions are such that the reagent is in the form of a gas. In most cases, the reagent reacts with functional groups on the surface of the particle and becomes bound to the particle. Because the reagent is a gas, it permeates into pores in the substrate and deposits onto the interior surfaces of the pores as well as onto the exterior surfaces of the substrate. This precursor is designed to react with the surface at all of the available surface sites but not react with itself. In this way, the first reaction occurs to form a single monolayer, or sub-monolayer, and creates a new surface functionality. Excess amounts of the reagent are then removed, which helps to prevent the growth of undesired, larger inclusions of the coating material. Each remaining half-reaction is then conducted in turn, each time introducing a first reagent, allowing it to react at the surface of the particle, and removing excess reagent before introducing the next reagent. Usually, an inert carrier gas is used to introduce the reagents, and the reaction chamber is usually swept with the carrier gas between successive reagent introductions to help remove excess reagents and gaseous reaction products. A vacuum may be pulled during and between successive dosings of reagents, to further remove excess reagents and gaseous reaction products.

After exposure to the first precursor, the surface is then exposed to the second precursor, also typically dispersed in an inert carrier gas. This precursor is designed to react with the functional groups put down in the first reaction step. This reaction also happens until all of the available surface sites are reacted. The second precursor also does not react with itself. Any excess of the second precursor is also removed in an optional inert gas purge step. If the gases are metered properly, the purge step may be unnecessary. This may be at least a 4 step process (precursor 1, purge, precursor 2, purge) to deposit one monolayer of the film which is being grown. This is not meant to imply only a single precursor because some ALD and MLD processes use multiple reactants in a step, for example APTES/H₂O/O₃ for depositing SiO₂. This process is repeated as many times as is necessary to build up the desired film thickness. The ALD/MLD process may start with a “linker” agent, or pre-treatment gas (such as ozone), that facilitates covalent bonding to the surface, or it may end with a terminating agent that may be hydrophobic, hydrophilic, or otherwise engineered for a specific purpose.

Reaction conditions are selected mainly to meet three criteria. The first criterion is that the reagents are gaseous under the conditions of the reaction. Therefore, temperature and pressure conditions are selected such that the reactants volatilize before reaction. The second criterion is one of reactivity. Conditions, particularly temperature, are selected such that the desired reaction between the film-forming reagents (or, at the start of the reaction, the first-introduced reagent and the particle surface) occurs at a commercially reasonable rate. The third criterion is that the substrate is thermally stable, from a chemical standpoint and from a physical standpoint. The substrate should not degrade or react at the process temperature, other than a possible reaction on surface functional groups with one of the ALD precursors at the early stages of the process. Similarly, the substrate should not melt or soften at the process temperature, so that the physical geometry, especially pore structure, of the substrate is maintained. The reactions are generally performed at temperatures from about 270 to 1000 K, preferably from 290 to 450 K, with specific temperatures in each case being below the temperature at which the substrate melts, softens or degrades.

Between successive dosings of the reagents, the particles are subjected to conditions sufficient to remove reaction products and unreacted reagents. This can be done, for example, by subjecting the particles to a high vacuum, such as about 10-5 Torr or greater, after each reaction step. Another method of accomplishing this, which is more readily applicable for industrial application, is to sweep the particles with an inert purge gas between the reaction steps. This purge gas can also act as a fluidizing medium for the particles and as a carrier for the reagents.

Several techniques are useful for monitoring the progress of the reaction. For example, vibrational spectroscopic studies can be performed using transmission Fourier transform infrared techniques. The deposited coatings can be examined using in situ spectroscopic ellipsometry. Atomic force microscopy studies can be used to characterize the roughness of the coating relative to that of the surface of the substrate. X-ray photoelectron spectroscopy and x-ray diffraction can be used to do depth-profiling and ascertain the crystallographic structure of the coating.

Aluminum oxide coatings are conveniently deposited using trimethylaluminum and water as the precursors, as illustrated by reaction sequence A1/B1. The illustrated reactions are not balanced, and are only intended to show the reactions at the surface of the substrate (i.e., not inter- or intralayer reactions).

Substrate-XH*+Al(CH₃)₃=Substrate-X—Al*—CH₃+CH₄ (precursor reaction)

Substrate-X—Al*—CH₃+H₂O=Substrate-X—Al—OH*+CH₄ (A1)

Substrate-X—Al—OH*+Al(CH₃)₃=Substrate-X—Al—O—Al*—CH₃+CH₄ (B1)

In reactions A1/B1, X is typically oxygen, nitrogen or sulfur, and the asterisk (*) represents the surface species at which the next half-reaction can occur. An aluminum oxide film is built up by repeating reactions A1 and B1 in alternating fashion, until the desired coating thickness is achieved. Aluminum oxide films tend to grow at a rate of approximately 0.1 nm/cycle using this reaction sequence.

Titanium oxide coatings are conveniently deposited using titanium tetrachloride and water and/or hydrogen peroxide as the precursors, as illustrated by reaction sequence A2/B2. As before, the illustrated reactions are not balanced, and are only intended to show the reactions at the surface of the particles (i.e., not inter- or intralayer reactions).

Substrate-XH*+TiCl₄=Substrate-X—Ti*—Cl₃+HCl (precursor reaction)

Substrate-X—Ti*—Cl₃+H₂O₂=Substrate-X—Ti*—OH+HCl+Cl₂ (A2)

Substrate-X—Ti*—OH+TiCl₄

Substrate-X—Ti—O—Ti*—Cl₃+—HCl (B2)

In reactions A2/B2, X is typically oxygen, nitrogen or sulfur, and the asterisk (*) represents the surface species at which the next half-reaction can occur. A titanium oxide film is built up by repeating reactions A2 and B2 in alternating fashion, until the desired coating thickness is achieved. Titanium oxide films tend to grow at a rate of approximately 0.05-0.1 nm/cycle using this reaction sequence.

As is known for ALD/MLD processes, the order can be AB, ABC, ABCD, ABCDABABCD, or any desired order provided that the chemical entities react with each other in the desired order. Each of the reactants has at least two reactive moieties (this includes the possibility that the reactant is modifiable to have two reactive moieties such as having a first reactive moiety and a second reactive moiety that is temporarily blocked by a protecting group or requires activation for subsequent reaction such as UV activation). In some preferred embodiments, the reactants have exactly two reactive moieties since higher numbers of reactive groups may lead to lower packing density. In some preferred embodiments, the films have at least three repeating units (e.g., ABABAB), or at least 5, or at least 10, or at least 50, and sometimes in the range of 2 to 1000, or 5 to 100. By “reactive” it is meant under normal MLD conditions and commercially relevant timescales (for example, at least 50% reacted within 10 hours under appropriate reaction conditions). For control of film quality, the reactants may be singly reactive during each step of the MLD process to avoid reacting twice to the surface, and the reactants should not self-react and condense onto the surface.

In some preferred embodiments, the reactive moieties for Reactant A may comprise: isocyanates (R—NCO), acrylates, carboxylic acids, esters, epoxides, amides and amines, and combinations thereof. In some preferred embodiments, Reactant A comprises a diisocyanate, a diacrylate, a dicarboxylic acid, a diester, diamide or a diamine. In some preferred embodiments, the reactive moieties on Reactant B comprise: alcohols or amines, and combinations thereof. In some preferred embodiments, Reactant B comprises a diol, an amine alcohol, or a diamine.

In some cases, especially for MLD, the vapor phase reactants selected react only monofunctionally with the substrate or growing polymer chain, i.e., only one group or moiety on the vapor phase reactant is capable of reacting with the substrate or growing polymer chain under the conditions of the reaction. This prevents unwanted cross-linking or chain termination that can occur when a vapor phase reactant can react polyfunctionally. A reactant is considered to react “monofunctionally” if during the reaction the reactant forms a bond to only one polymer chain, and does not self-polymerize under the reaction conditions employed. As explained more fully below, it is possible in certain embodiments of the invention to use a vapor phase reactant that can react difunctionally with the substrate or growing polymer chain, provided that the vapor phase reactant contains at least one additional functional group. Reactants that have exactly two functional groups which have approximately equal reactivity are preferably avoided in this aspect of invention.

A first class of suitable vapor phase reactants are compounds having two different reactive groups, one of which is reactive with a functional group on the substrate or polymer chain and one of which does not readily react with a functional group on the polymer chain but is reactive with a functional group supplied by a different vapor phase reactant. Examples of reactants of this class include:
a) Hydroxyl compounds having vinyl or allylic unsaturation. These can react with a carboxylic acid, carboxylic acid halide, or siloxane group to form an ester or silicone-oxygen bond and introduce vinyl or allylic unsaturation onto the polymer chain. Alternatively, the unsaturated group can react with a primary amino group in a Michaels reaction to extend the polymer chain and introduce a hydroxyl group onto the chain.
b) Aminoalcohol compounds. The amino group can react with a carboxyl group, a carboxylic acid chloride, a vinyl or allylic group, or an isocyanate group, for example, to extend the polymer chain and introduce a hydroxyl group onto the chain. Alternatively, the hydroxyl group can react with a siloxane species to form a silicon-oxygen bond and introduce a free primary or secondary amino group.

A second class of suitable vapor phase reactants includes various cyclic compounds which can engage in ring-opening reactions. The ring-opening reaction produces a new functional group which does not readily react with the cyclic compound. Examples of such cyclic compounds include, for example:
a) Cyclic azasilanes. These can react with a hydroxyl group to form a silicon-oxygen bond and generate a free primary or secondary amino group.
b) Cyclic carbonates, lactones and lactams. The carbonates can react with a primary or secondary amino group to form a urethane linkage and generate a free hydroxyl group. The lactones and lactams can react with a primary or secondary amino group to form an amide linkage and generate a free hydroxyl or amino group, respectively.

A third class of vapor phase reactants includes compounds that contain two different reactive groups, both of which are reactive with a functional group on the polymer chain, but one of which is much more highly reactive with that functional group. This allows the more reactive of the groups to react with the functional group on the polymer chain while leaving the less reactive group unreacted and available for reaction with another vapor phase reactant.

A fourth class of vapor phase reactants includes compounds that contain two reactive groups, one of which is blocked or otherwise masked or protected such that it is not available for reaction until the blocking, masking or protective group is removed. The blocking or protective group can be removed chemically in some cases, and in other cases by thermally decomposing the blocking group to generate the underlying reactive group, by radiating the group with visible or ultraviolet light, or in a photochemical reaction. The unprotected group may be, for example, an amino group, anhydride group, hydroxyl group, carboxylic acid group, carboxylic anhydride group, carboxylic acid ester group, isocyanate group and the like. The protected group may be one which, after removal of the protective group, gives rise to a functional group of any of the types just mentioned.

A reactant of this fourth class may, for example, have a hydroxyl group protected by a leaving group such as a benzyl, nitrobenzyl, tetrahydropyranyl, —CH₂OCH₃ or similar group. In these cases, the hydroxyl group can be deprotected in various ways, for example by treatment with HCl, ethanol, or in some cases, irradiation. Carboxyl groups can be protected with leaving groups such as —CH₂SCH₃, t-butyl, benzyl, dimethylamino and similar groups. These groups can be deprotected by treatment with species such as trifluoroacetic acid, formic acid, methanol or water to generate the carboxylic acid group. Amino groups can be protected with groups such as R—OOC—, which can be removed by reaction with trifluoroacetic acid, hydrazine or ammonia. Isocyanate groups can be protected with carboxyl compounds such as formic acid or acetic acid.

A fifth class of vapor phase reactants contains a first functional group, and a precursor group at which a further reaction can be conducted to produce a second functional group. In such a case, the first functional group reacts to bond to the polymer chain, and chemistry is then performed at the precursor group to generate a second functional group. The first functional group can be any of the types mentioned before, including a siloxane group, amino group, anhydride group, hydroxyl group, carboxylic acid group, carboxylic anhydride group, carboxylic acid ester group, isocyanate group and the like. A wide variety of precursor groups can be present on this type of reactant.

The precursor group may be one that it does not itself react with the polymer chain, but it can be converted to a functional group that can react with another vapor phase reactant to grow the chain. Two notable types of precursor groups are vinyl and/or allylic unsaturation, and halogen substitution, especially chlorine or bromine. Vinyl and allylic unsaturation can be converted to functional groups using a variety of chemistries. These can react with ozone or peroxides to form carboxylic acids or aldehydes. They can also react with ammonia or primary amino to produce an amine or imine. Halogens can be displaced with various functional groups. They can react with ammonia or primary amine to introduce an amino group, which can in turn be reacted with phosgene to produce an isocyanate group, if desired.

Reactants that are used to convert a precursor group to a functional group or to demask or deprotect a functional group, are introduced in the vapor phase. Excess reactants of this type are removed prior to the introduction of the next reactant, typically by drawing a high vacuum in the reaction zone, purging the chamber with a purge gas, or both. Reaction by-products are removed in the same manner, before introducing the next reactant into the reaction zone

In some preferred embodiments at least one or all of the reactants in the MLD repeating units have chain lengths between reactive moieties of from 2 to 20 atoms (typically carbon atoms although heterogroups such as oxygen may be present), or from 2 to 10 atoms, or from 2 to 5 atoms. In some preferred embodiments, the reactants have straight chains (i.e., no branching) between reactive moieties to enhance packing density. In some preferred embodiments, the chains between reactive moieties are non-reactive; however, in some embodiments, there may be moieties within the chains that are capable of cross-linking to adjacent chains. In some embodiments, the capping layer and/or the MLD layers at or very near the surface (e.g., within 5 cycles or within 2 cycles of the capping layer or surface) are branched for enhanced hydrophobicity.

An inorganic layer applied to the particle in a first step preferably becomes covalently bonded to the substrate. Covalent bonding can occur when the first-to-be-applied precursor compound reacts under the conditions of the atomic layer deposition process with a functional group on the surface of the substrate. Examples of such functional groups are, for example, hydroxyl, carbonyl, carboxylic acid, carboxylic acid anhydride, carboxylic acid halide, primary or secondary amino.

Some ALD coatings are aluminum oxide and/or titanium oxide coatings. “Aluminum oxide” is used herein to designate a coating that is made up substantially entirely of aluminum and oxygen atoms, without reference to the specific stoichiometry. In many cases, it is expected that an aluminum oxide coating will correspond somewhat closely to the empirical structure of alumina, i.e., Al₂O₃, although deviations from this structure are common and may be substantial. “Titanium oxide” is used herein to designate a coating that is made up substantially entirely of titanium and oxygen atoms, without reference to the specific stoichiometry. In most cases, it is expected that a titanium oxide coating will correspond closely to the empirical structure of titania, i.e., TiO₂, although deviations from this structure are common and may be substantial.

Except for the case of a half-reaction included in the broader aspects of the present invention, the atomic layer deposition process is characterized in that at least two different reactants are needed to form the coating layer. The reactants are introduced into the reaction zone individually, sequentially and in the gas phase. Excess amounts of reactant are removed from the reaction zone before introducing the next reactant. Reaction by-products are removed as well, between successive introductions of the reagents. This procedure ensures that reactions occur at the surface of the substrate, rather than in the gas phase.

A purge gas is typically introduced between the alternating feeds of the reactants, in order to further help to remove excess reactants. A carrier gas, which is usually but not necessarily the same as the purge gas, generally (but not always necessarily) is introduced during the time each reactant is introduced. The carrier gas may perform several functions, including (1) facilitating the removal of excess reactant and reaction by-products and (2) distributing the reactant through the reaction zone, thereby helping to expose all surfaces to the reactant. The purge gas does not react undesirably with the ALD reactants or the deposited coating, or interfere with their reaction with each other at the surface of the substrate.

Temperature and pressure conditions will depend on the particular reaction system, as it remains necessary to provide gaseous reactants. As is known for ALD/MLD processes, the temperature should be high enough to enable reactants in the gas phase but not so high that the product degrades.

The ALD/MLD coating may comprise any coating that can be applied by molecular or atomic layer deposition. Some well-known coatings that can be applied to the metallic or other material core particle may comprise: oxides or mixed oxides (e.g., Al₂O₃, TiO₂, ZnO, ZrO₂, SiO₂, HfO₂, Ta₂O₅, LiNbₓO_{y}), nitrides (e.g., TiN, TaN, W₂N, TiY₂N), sulfides (e.g., ZnS, CdS, SnS, WS₂, MoS₂, ZnIn₂S₄), and phosphides (e.g., GaP, InP, Fe_{0.5}Co_{0.5}P). Some lesser known materials that can be applied to the core particle may comprise: transition metals (e.g., of Al, Cu, Co, W, Cr, Fc, Zn, Zr, Pt, Pd), metal fluorides (e.g., AlF₃, MgF₂, ZnF₂), oxy fluorides and oxy nitrides of transition metals, lanthanides in either elemental, oxide, fluoride, nitride, boride, or sulfide form (e.g., Y, YN, La₂O₃, LaF₃, Nb, Dy₂O₃, Nd, LaB₆, La₂S₃ etc.), borides (e.g., TiB₂), carbides (e.g., B₄C, WC), silanes, silicides and other silicon containing materials, carbon-containing materials including, but limited to, polymers (e.g., polyamides, polyethylenes, polyamides, polyureas, polyurethanes), hydrocarbons, polymers or fragments of amino acids or other biological-related molecules and polymers, and other materials), fluorinated polymers (e.g., fluoro or perfluoro-polyamides, -polyethylenes, -polyamides, -polyureas, -urethanes, -hydrocarbons). This coating is highly uniform over the particle; preferably, there is no more than a 20%, more preferably no more than 10%, or no more than 5% variation in coating thickness over the surface of the particle. This high level of uniformity is a characteristic of the ALD/MLD process.

### EXAMPLE

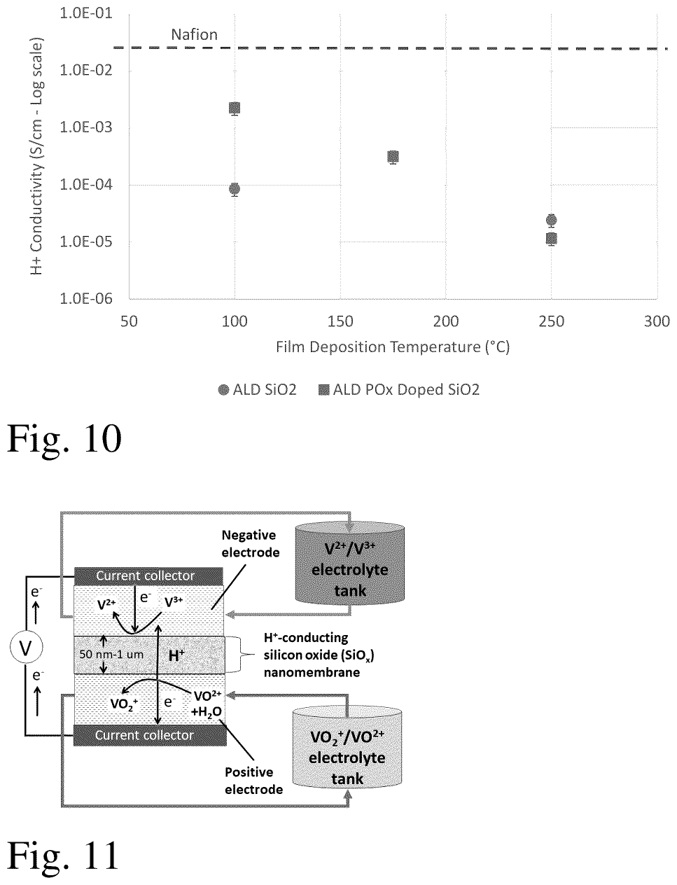

We have developed a film that has the highest room temperature proton (H+) conductivity at room temperature disclosed in literature. At the deposition temperature of 100° C. with ˜0.5% POₓ content, as measured by x-ray photoemission spectroscopy (XPS), the film has H+ conductivity of 2.2 mS/cm. This is almost an order of magnitude above the current literature best, 2.4×10⁻¹ mS/cm (Prakash, et al., J. Pow. Sources, 175, 2008) and close to the state of the art for vanadium redox flow batteries (VRFB), 30-80 mS/cm, for Nafion212. FIG. 10 shows the H+ conductivity behavior of both POx doped and undoped SiOx with respect to deposition temperature, the Nafion baseline is shown as the dashed line.

This high H+ conductivity allows for a small membrane resistance (mΩ·cm²), the first of two critical metrics, in VRFBs. Membrane resistance is the product of H+ resistivity and thickness, and while the H+ resistivity is higher for POx doped SiOx than Nafion, a significant reduction in thickness is possible with the ALD film, allowing for the overall membrane resistance to be lower. For example, the state-of-the-art Nafion212 film is at least 50 microns, while the ALD membrane is useful at less than 500 nm or at least two orders of magnitude thinner. This thinner total thickness more than makes up for the lower H+ conductivity of the ALD film. Nafion has hit the inherent thickness limitations, as the V ion crossover increases as Nafion becomes thinner. This shows up as the membrane ion selectivity (S·min/cm³), which is the ratio of H⁺ conductivity to the V ion permeability and is the second critical metric for VRFBs. The higher membrane ion selectivity the higher coulombic efficiency one gets from the battery. Current Nafion films have troublesome V ion permeability, ˜5×10⁵ cm²/min, at current thickness, so the industry has been looking for polymer alternatives that improve V ion permeability, without sacrificing H⁺ conductivity. Our ALD POx doped SiOx film has high enough H⁺ conductivity, at orders of magnitude thinner film, with far superior V ion permeability, providing 1-3 orders of magnitude improvement in membrane ion selectivity over Nafion. While we don't have direct measurements of V ion permeability, we can infer the performance from two places. First, the transport of a neutral molecule, H₂, that is much smaller than that of hydrated V³⁺. In experiments the ALD film has a H₂ permeability of 4.9×10⁻⁹ cm²/min and Nafion212 has a H₂ permeability of 5.2×106 or over three orders of magnitude lower. Second, in tests on a similar, though inferior, SiOx material, the Fe³⁺ ion permeability at 5 nm was measured to be 3×10⁻⁸ cm²/min, which would be again 3 orders of magnitude lower than Nafion (for V³⁺). When taken together, the lower membrane resistance and higher membrane ion selectivity will provide a more efficient VRFB with equal or longer lifetimes. A vanadium redox flow battery (VFRB) is illustrated in FIG. 11.

There are other aspects of replacing Nafion with a ceramic membrane that are worth noting. Nafion is a PFAS chemical. Providing the marketplace with a non-PFAS alternative is critical at this juncture. In addition, polymer membranes, such as Nafion, have a swelling problem that causes wrinkling during manufacturing. Nafion can swell and increase the aerial dimensions by 20%, the ALD ceramic film has negligible change in dimensions. ALD can also be added to existing components, such as carbon paper current collectors, improving large scale manufacturing.

What is claimed:

1. An electrolyzer, comprising:
an anode, a cathode, and a doped silica electrolyte layer;
wherein the anode and the cathode separated by one μm or less;
wherein the anode and the cathode are separated by the doped silica electrolyte layer;
wherein the doped silica electrolyte layer has:
a thickness of 5 to 1000 nm;
a dopant:silicon atomic ratio of 0.1:99.5 to 15:85; and one or any combination of the following room temperature properties:
a H+ permeability (cm²/s)≥5×10⁻¹¹;
a H+ conductivity of at least 0.5 mS/cm, or at least 1.0 mS/cm, or in the range of 0.5 to 5 mS/cm, or in the range of 1.0 to 4 mS/cm;
an H₂ permeability of 8×10⁻¹¹ cm²/s or less; or
a vanadium ion permeability of 1×10⁻⁸ cm²/min or less.

2. The electrolyzer of claim 1 wherein the electrolyzer is a redox flow battery.

3. The electrolyzer of claim 1 wherein the doped silica electrolyte layer is deposited on the anode by atomic layer deposition.

4. The electrolyzer of claim 1 wherein the anode comprises carbon paper.

5. The electrolyzer of claim 1 wherein no fluoropolymer is present.

6. The electrolyzer of claim 1 wherein the doped silica electrolyte layer has a thickness in the range of 5-500, 5-200, 5-100, 10-1000, 10-500, 10-200, 10-100 nm.

7. The electrolyzer of claim 1 wherein the doped silica electrolyte layer has a dopant:silicon atomic ratio of 0.2:99 to 15:85; 0.5:99 to 15:85; or 1:99 to 10:90; or 1:99 to 5:95.

8. The electrolyzer of claim 1 wherein the doped silica electrolyte layer has a H+ permeability ≥1×10⁻¹⁰; or in the range of 5×10⁻¹¹ to 5×10⁻¹⁰; or in the range of 5×10⁻¹¹ to 2×10⁻¹⁰ cm²/s and a H+ conductivity of >1×10⁻³; or in the range of 5×10⁻⁵ to 2×10⁻³; or in the range of 5×10⁻⁵ to 2×10⁻³ S/cm.

9. The electrolyzer of claim 1 wherein the dopant is P⁺⁵.

10. A doped silica layer on a substrate, comprising:
the substrate; and
the doped silica layer that has:
a thickness of 5 to 1000 nm;
a dopant:silicon atomic ratio of 0.1:99.5 to 15:85
wherein the dopant is P⁺⁵.

11. The doped silica layer on a substrate of claim 10 having a thickness in the range of 5-500, 5-200, 5-100, 10-1000, 10-500, 10-200, 10-100 nm.

12. The electrolyzer of claim 10 wherein the doped silica layer has a dopant:silicon atomic ratio of 0.2:99 to 15:85; 0.5:99 to 15:85 or 1:99 to 10:90; or 1:99 to 5:95.

13. The doped silica layer on a substrate of claim 10 having a H⁺ permeability ≥1×10⁻¹⁰; or in the range of 5×10⁻¹¹ to 5×10⁻¹⁰; or in the range of 5×10⁻¹¹ to 2×10⁻¹⁰ cm²/s and a H⁺ conductivity of ≥1×10⁻³; or in the range of 5×10⁻⁵ to 2×10⁻³; or in the range of 5×10⁻⁵ to 2×10⁻³ S/cm.

14. The doped silica layer on a substrate of claim 10 wherein the substrate comprises a cathode, an anode, or glass.

15. A method of making a doped silica layer on a substrate, comprising:
providing a substrate;
applying a silica layer by CRISP ALD on the substrate; and
treating the silica layer with a phosphorus-gas in which phosphorus is in the +3 oxidation state.

16. The method of claim 15 wherein the phosphorus-gas comprises trialkoxyphosphite.

17. The method of claim 15 wherein the phosphorus-gas comprises trimethoxyphosphite.

18. The method of claim 15 wherein the CRISP ALD comprises from 5 to 30 cycles followed by one to five cycles of treatment with the phosphorus-gas.

19. The method of claim 18 wherein a cycle comprises from 5 to 30 cycles of CRISP ALD followed by one to five cycles of treatment with the phosphorus-gas; and comprising a plurality of cycles to form a thicker layer.

20. The method of any of claim 15 wherein the applying step is conducted at a temperature of 200° C. or less, or 175° C. or less, or 150° C. or less.
